(19) United States
(12) Patent Application Publication
(10) Pub. No.: US 2013/0199916 A1
(43) Pub. Date: Aug. 8, 2013

(54) ELONGATIONAL STRUCTURES

(71) Applicant: Takashi Iwamoto, Urayasu-shi (JP)

(72) Inventor: Takashi Iwamoto, Urayasu-shi (JP)

(73) Assignee: Empire Technology Development LLC, Wilmington, DE (US)

(21) Appl. No.: 13/641,843

(22) PCT Filed: Feb. 8, 2012
(86) PCT No.: PCT/US2012/024322

§ 371 Date: Oct. 17, 2012

(51) Int. Cl. H01B 7/00; H03K 17/96; H01B 1/04; H01B 1/02; H01B 1/08

(52) U.S. Cl. CPC H01B 7/00; H01B 1/02; H01B 1/08; H01B 1/04; H03K 17/962; B82Y 30/00
USPC 200/600; 428/161; 428/164; 427/58; 427/123; 427/126.3; 427/122; 977/742; 977/734

(57) ABSTRACT

The present disclosure generally relates to expandable electrodes and/or components that are expandable and/or flexible during, prior to, and/or after the manufacture of the electrodes.

### BACKGROUND

Traditionally, the process of forming electrodes on transparent substrates generally involves high-temperature treatment. In addition, the material frequently used as a transparent substrate is usually a highly heat-resistant substrate, such as glass.

### SUMMARY

Some embodiments provided herein relate to an electrode. In some embodiments, the electrode can include a nonconductive substrate having a plurality of grooves. In some embodiments, the plurality of grooves can have inner walls. In some embodiments, the electrode can also include a conductive layer disposed on the substrate and the inner walls of at least one of the plurality of grooves. In some embodiments, part or all of the substrate can be elastic.

In some embodiments, a method of preparing an electrode is provided. The method can include providing a nonconductive substrate including at least one groove. The at least one groove can include at least one inner wall. The method can also include applying a conductive layer to the nonconductive substrate and the at least one inner wall. In some embodiments, the substrate can be elastic.

In some embodiments, a method of using an interactive device is provided. The method can include providing a device including a flexible electrode. The flexible electrode can include a nonconductive substrate including a plurality of grooves, where the plurality of grooves can have inner walls, and a conductive layer disposed on the substrate and the inner walls of at least one of the plurality of grooves. The method can further include flexing the flexible electrode to a flexed state, thereby interacting with the device.

The foregoing is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIGS. 1A-1D are schematic diagrams depicting how to prepare an electrode in accordance with some embodiments.

FIGS. 2A-2C are drawings depicting top plan views of electrodes having various groove patterns

FIG. 2A is a drawing depicting an electrode with a groove pattern in accordance with some embodiments.

FIG. 2B is a drawing depicting an electrode with a groove pattern in accordance with some embodiments.

FIG. 2C is a drawing depicting an electrode with a groove pattern in accordance with some embodiments.

FIG. 3 is a drawing depicting a system for preparing an electrode in accordance with some embodiments.

FIG. 4 is a drawing depicting a system for preparing an electrode in accordance with some embodiments.

FIG. 5 is a flowchart illustrating some embodiments for preparing an electrode.

### DETAILED DESCRIPTION

In the following detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein, and illustrated in the Figures, can be arranged, substituted, combined, separated, and designed in a wide variety of different configurations, all of which are explicitly contemplated herein.

In some embodiments, the methods and apparatuses disclosed herein generally relate to an electrode. In some embodiments, the electrode can be an expandable and/or flexible and/or stretchable electrode. In some embodiments, the electrode can be transparent and expandable. In some embodiments, the electrode can include a nonconductive substrate having a plurality of grooves with each of the grooves having inner walls. The electrode can also have a conductive layer disposed on the substrate and the inner walls of the plurality of grooves. In some embodiments, the grooves can be disposed in a grid pattern. In some embodiments, the ratio of the depth of the grooves to the width of the grooves can be at least about one.

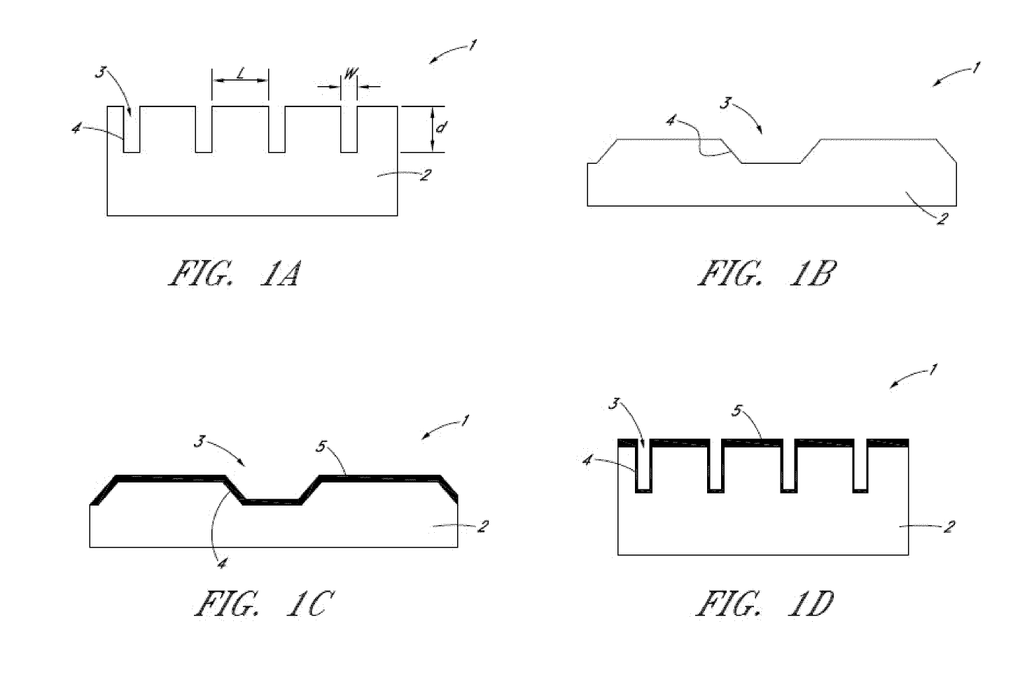

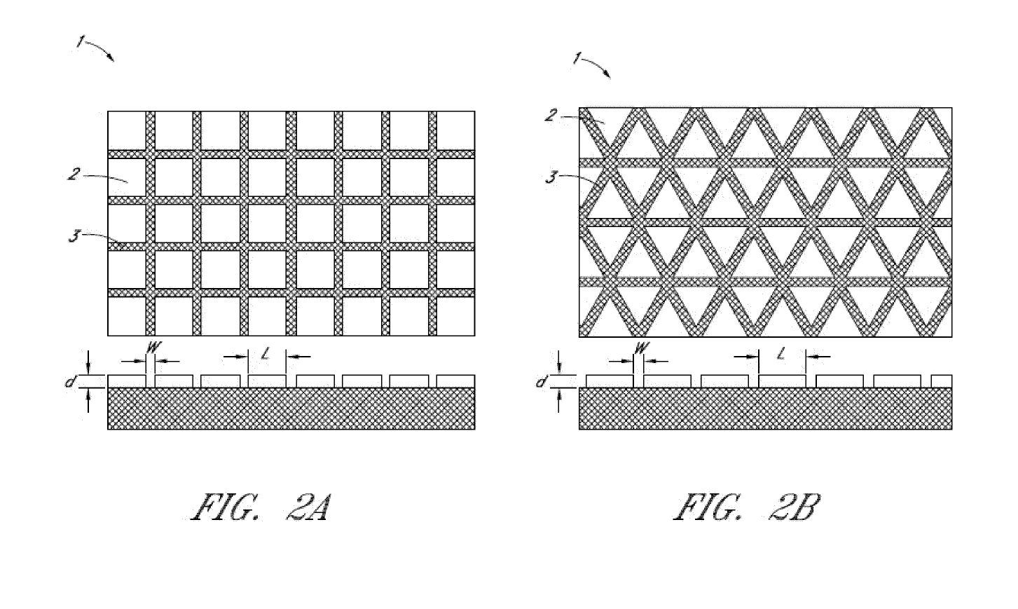

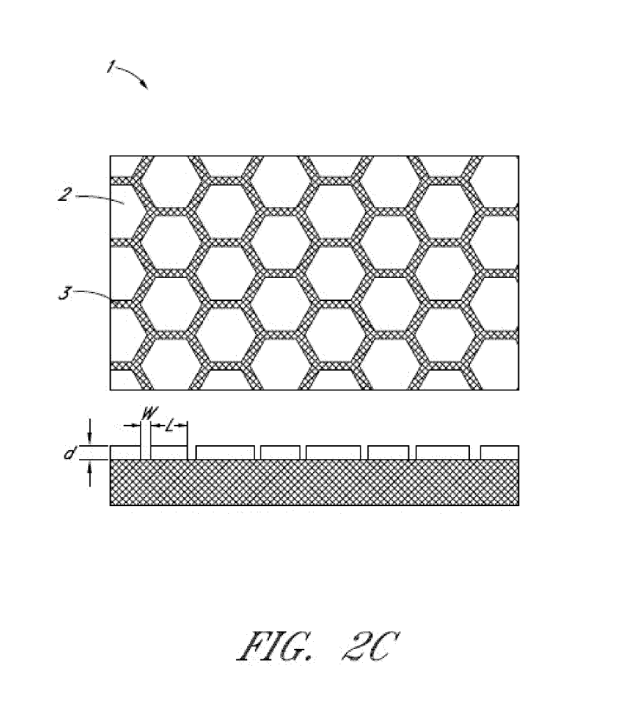

FIGS. 1A-1D depict some embodiments for preparing an electrode and some embodiments of the electrode itself. Each schematic diagram of FIGS. 1A-1D illustrates changes to the surface of an electrode 1. One skilled in the art, given the present disclosure, will appreciate that, for this and other processes and methods disclosed herein, the functions performed in the processes and methods may be implemented in differing order. Furthermore, the outlined steps and operations are only provided as examples, and some of the steps and operations may be optional, combined into fewer steps and operations, or expanded into additional steps and operations without detracting from the essence of the disclosed embodiments.

As illustrated in FIG. 1A, in some embodiments, a nonconductive film or substrate 2 is provided. In some embodiments, the substrate 2 can have a plurality of slits or grooves 3. In some embodiments, each of the grooves 3 can have a one or more of inner walls 4. In some embodiments, each of the grooves 3 has a depth d and a width W. The spacing between the grooves 3 can be represented by a pitch L.

As shown in FIG. 1B, in some embodiments where, a nonconductive substrate 2 is provided, the substrate 2 can be elongated (e.g., expanded). In some embodiments, a tensional force can be applied to the substrate before (and/or during and/or after) applying a conductive layer 5. In some embodiments, sufficient tension can be applied so that a width of a bottom surface of the groove 3 expands. In some embodiments, sufficient tension can be applied so that a width of a top of the groove 3 expands. In some embodiments, the tension can be applied so that it is sufficient to cause the at least one inner wall 4 of the groove 3 to bend at an angle greater than 90 degrees (as measured from the bottom surface).

As shown in FIG. 1C, in some embodiments, where a nonconductive substrate 2 is elongated or expanded, an electrode pattern or conductive layer 5 can be applied to the substrate 2 and the least one inner wall 4. In some embodiments, the conductive layer 5 is applied while the tension is applied to the substrate 2. In some embodiments, the conductive layer 5 is applied by a low-temperature vapor deposition. For example, the low-temperature vapor deposition can apply sputtering or other metallization techniques. In some embodiments, the low-temperature vapor deposition technique can provide sufficient step coverage to cover over the substrate 2 and the inner walls 4. In some embodiments, the stretched conformation during the application of the conductive layer 5, allows for ease of deposition of a material on a surface 4 of a wall, bottom of the groove, and/or both. In some embodiments, applying the conductive layer 5 over a stretched substrate 2 allows the substrate to return to the stretched state, without resulting in (or reducing any) physical damage to the conductive layer due to the stretching movement. In some embodiments, applying the conductive layer 5 over a stretched substrate 2 allows the substrate to stretch more readily, as there is sufficient conductive layer 5 to extend to the stretched state, without having to stretch the material of the conductive layer itself (although, in some embodiments, the conductive layer itself can be stretchable). In some embodiments, any one, two, three, or none of the above advantages can be relevant to a particular device and/or method.

In some embodiments, the conductive layer 5 is transparent to light or is at least partially transparent to light. In some embodiments, the light can be visible light (though it need not be limited to visible light and can be, for example transparent to UV and/or infrared light). In some embodiments, the light has a wavelength from 200 nm to 700 nm, e.g., 200, 210, 220, 240, 260, 280, 300, 320, 340, 360, 380, 400, 420, 440, 460, 480, 500, 520, 540, 560, 580, 600, 620, 640, 660, 680, or 700 nm, including any range defined between any two of the preceding values.

In some embodiments, the conductive layer 5 can be made of a material such as ZnO, indium tin oxide (ITO), Poly(3,4-ethylenedioxythiophene) (PEDOT), carbon nanotubes, grapheme, metal, metal alloy, conductive polymer, or combinations thereof.

In some embodiments, as illustrated in FIG. 1D, the tension applied to the substrate 2 (e.g., as shown in FIG. 1C) can be released to allow the electrode 1 to return to its initial conformation or at least a close to its initial conformation. In some embodiments, this allows for an electrode or device that has the shape as shown in FIG. 1A and/or FIG. 1C, while having a conductive layer 5 as shown. In some embodiments, this allows for superior and/or consistent coverage of the electrode 5, even when the groove 3 has deep walls 4 and/or a relatively narrow width (which might otherwise present challenges to some coating techniques. While this can result in superior coverage of the electrode layer 5 (or any other layer that is applied when the substrate 2 is stretched), in some embodiments, it is the continued ability of the electrode 1 to be expandable (e.g., to shift from the arrangement in FIG. 1C to that in FIG. 1D) and/or flexible that can be advantageous. In some embodiments, the electrode can be expandable. In some embodiments, the electrode 1 can be flexible. In some embodiments, the electrode 1 can be visibly transparent or at least partially visibly transparent.

In some embodiments, the electrode 1 can transition from a stretched state (e.g., as shown in FIG. 1C) to a resting state (e.g., as shown in FIG. 1D) at least two times, e.g., 2, 5, 10, 50, 100, 1000, 10,000, 100,000, 1,000,000 or more times. In some embodiments, while the change in conformation may, eventually, reduce flexibility (and/or the final resting conformation and/or stretched conformation), the structure returns to at least an approximation of either the resting and/or stretched state after any or all of the above noted transitions. In some embodiments, it returns (or can be stretched) to within at least 99, 95, 90, 80, 70, 60, 50, 40, 30, 20, 10, or 5% of where the structures could be stretched to (or return to) after the first transition.

In some embodiments, the electrode 1 as illustrated in FIG. 1D can be a flexible electrode as part of an interactive device and/or input system. In some embodiments, the electrode 1 can be part of a display system on the interactive device, such as a touch sensitive screen. In some embodiments, the flexible electrode can be part of a display surface. In some embodiments, the flexible electrode can be part of a mobile phone, music player, computer screen, tablet, electronic books, and/or navigation device.

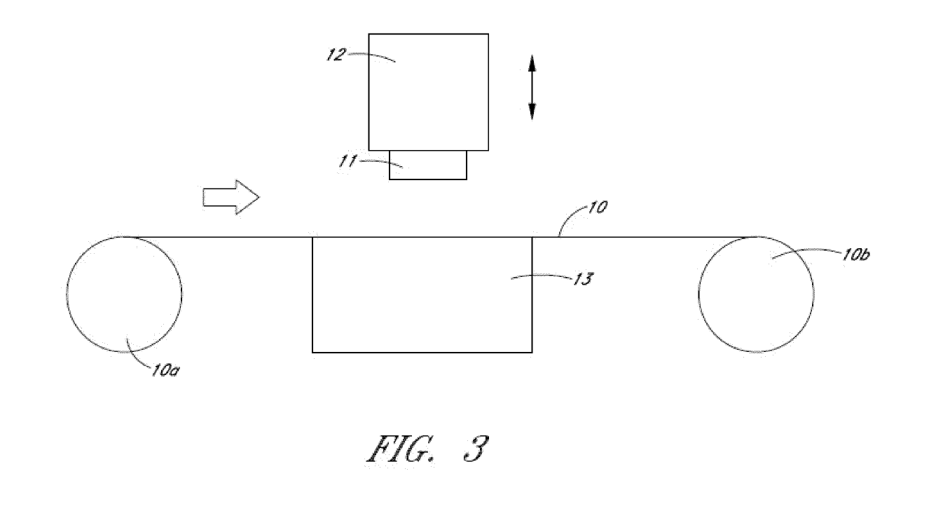

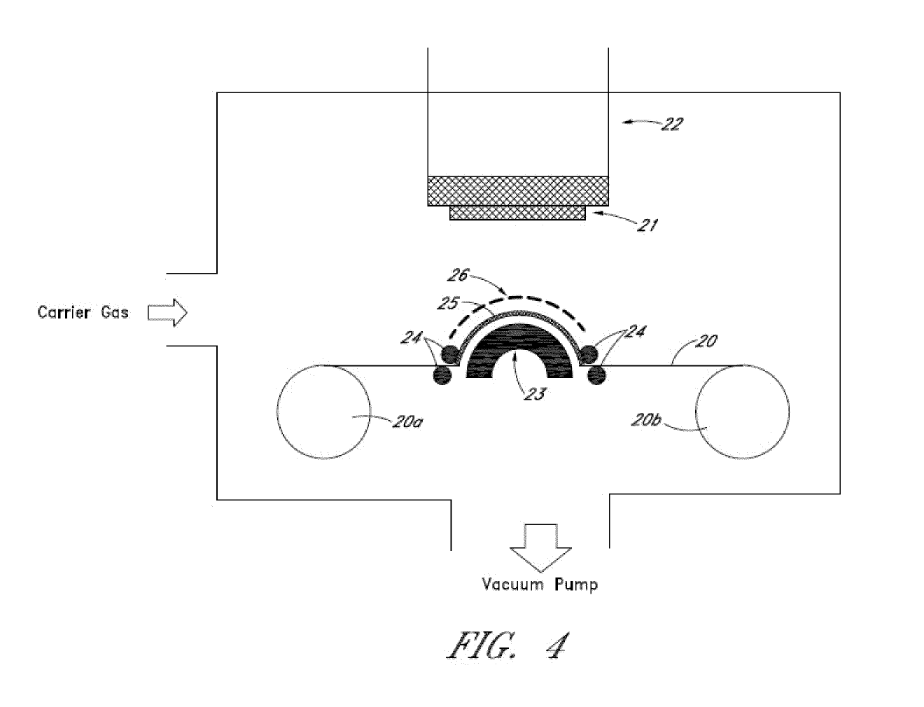

In some embodiments, the electrodes can be part of an array of electrodes. In some embodiments, only a single flexible electrode is present and/or employed. One of skill in the art will appreciate that any number and/or variety of shapes and configurations of the electrodes can be employed. Some embodiments of some shapes and electrode arrangements are depicted in FIGS. 2A-2C. These figures illustrate top plan views of schematic diagrams of electrodes having various slit or groove patterns. In FIGS. 2A-2C, each of the electrodes 1 has grooves 3 disposed in a grid pattern. In some embodiments, the grooves 3 are disposed in a grid pattern having a plurality of intersection junctions. In some embodiments, each intersection junction can be connected to at least two other intersection junctions by the grooves 3.

FIG. 2A depicts some embodiments in which the electrode 1 can include grooves 3 disposed in a mesh pattern including a plurality of squares or rectangles.

In some embodiments, as depicted in FIG. 2B, the electrode 1 can include grooves 3 disposed in a mesh pattern including a plurality of triangles.

In some embodiments, as depicted in FIG. 2C, the electrode 1 can include grooves 3 disposed in a honeycomb hexagonal mesh pattern. In some embodiments, the grooves do not need to be linear. In some embodiments, the grooves can be curved. In some embodiments, the grooves can vary in width and/or depth and/or pitch along the length of the groove.

A skilled artisan will appreciate, given the present disclosure, that these and other suitable types of mesh patterns can be applied. In some embodiments, the pattern can be determined based upon the direction and/or degree in which the stretching and/or bending is expected, or, for example, based upon the use of the device.

In FIGS. 2A-2C, each of the grooves 3 can have a depth d and a width W, and a spacing between the grooves 3 represented by a pitch L. The ratio of the depth d of the grooves 3 to the width W of the grooves can be represented as an aspect ratio d/W. In some embodiments, the aspect ratio d/W is about one. In some embodiments, the higher the aspect ratio, the more the electrode 1 is allowed to expand. As will be appreciated by one of skill in the art, a variety of aspect ratios can be employed. In some embodiments, the aspect ratio is 1 or lower. In some embodiments, the aspect ratio is 1 or higher. In some embodiments, the aspect ratio can be 0.1, 0.2, 0.3, 0.4, 0.5, 0.6, 0.7, 0.8, 0.9, 1, 1.1, 1.2, 1.3, 1.4, 1.5, 1.6, 1.7, 1.8, 1.9, 2, 3, 4, 5, 6, 7, 8, 9, 10, 20, 30, 40, 50, 60, 70, 80, 90, 100 or more, including any range defined between any two of the preceding values and any range above any one of the preceding values.

In some embodiments, the width W can be small enough to achieve a high aspect ratio. For example, the width W of the grooves 3 can be about 375 nm or less. In some embodiments, the grooves 3 can have a width W of about 195 nm to about 375 nm (e.g., 195, 200, 210, 220, 230, 240, 250, 260, 270, 280, 290, 300, 310, 320, 330, 340, 350, 360, 370 or 375). In some embodiments, the width W of the grooves 3 can be about 275 nm or less. In some embodiments, the width W can be less than or equal to about one-half the wavelength of visible light, e.g. less than or equal to half of one or more of 380 nm to 740 nm. In some embodiments, the width W is 375 nm, 325 nm, 275 nm, 250 nm, 225 nm, 195 nm, or 175 nm. In some embodiments, the width is less than 370 nm, e.g., 369, 368, 367, 366, 365, 360, 350, 340, 330, 320, 310, 300, 290, 280, 270, 260, 250, 240, 230, 220, 210, 200, or 190 nm.

In some embodiments, the depth d is small enough to allow for sufficient optical transparency. In some embodiments, the grooves 3 can have a depth d of about 195 nm or more. In some embodiments, the depth d of the grooves 3 can be about 275 nm or more. In some embodiments, the depth d is 195 nm, 225 nm, 250 nm, 275 nm, 325 nm, 375 nm, 425 nm, or 465 nm.

In some embodiments, the aspect ratio is as high as possible or is maximized. In some embodiments, the width can be minimized or reduced to as low a point as possible. In some embodiments, this allows one to have an optically high-quality transparent electrode. In some embodiments, the depth can be maximized or increased to as great a level as possible.

In some embodiments, if the depth d is smaller than the aforementioned values and the width W is greater than the aforementioned values, then the optical transparency of the electrode 1 can increase while the elasticity of the electrode 1 can decrease.

In some embodiments, the substrate can be made of a non-highly heat resistant material. In some embodiments, the substrate can be nonconductive. In some embodiments, the substrate can be transparent. In some embodiments, the substrate is and/or includes plastic. In some embodiments, the substrate can be made of a flexible and/or elastic material. In some embodiments, the substrate can be made of a rigid material. In some embodiments, the substrate can be made of a material such as an elastomer, a polymer, PET, a high transparency polyimide, or a combination thereof.

In some embodiments, the substrate 2 can be made of a material such as a polymer, an elastomer, a liquid crystal polymer, or a combination thereof. In some embodiments, the substrate can be made of a material such as a polyimide, polyester, aramid, epoxy, silicone, rubber, protein, cellulosic materials, or a combination thereof. In some embodiments, the substrate can be made of a material such as a block copolymer of methyl methacrylate and butyl acrylate. For example, a block copolymer of methyl methacrylate and butyl acrylate can be KURARITY as manufactured by Kuraray Co., Ltd.

In some embodiments, the substrate can be made of a material having a glass transition temperature lower than about −40° C. (e.g., less than −41, −42, −43, −44, −45, −50, −60, −70° C., or lower, including any range lower than any of the preceding values). In some embodiments, the substrate can be made of a material having a loss-on-ignition onset temperature of about 250° C. or above. In some embodiments, the substrate can be a material having a thermal deformation temperature of about 150° C. or above (e.g., 145, 150, 155, 160, 170, 180, 200, 300, 400, or 500° C., including any range above any of the preceding values). In some embodiments, the substrate can be made of a suitable material having more than one of the aforementioned properties simultaneously.

FIG. 3 depicts a schematic diagram of a system for preparing an electrode in accordance with some embodiments. The system in FIG. 3 illustrates a method for providing a nonconductive substrate 10 with at least one groove (not shown). The at least one groove can have at least one wall (not shown). In some embodiments, providing the substrate 10 can include forming the groove in the substrate 10. Forming the groove can include forming a nano scale pattern on silicon using a nano imprinting mold 11 corresponding to the nano scale pattern.

As illustrated in FIG. 3, forming a nano scale pattern can include feeding an elastomer sheet 10 from a first side 10a where the elastomer sheet 10 is in a rolled up form. In some embodiments, the elastomer sheet 10 can be fed continuously from the first side 10a to a second side 10b. In some embodiments, the elastomer sheet 10 is continuously fed over a stage 13 for hot stamping. In some embodiments, above the stage 13 there can be a moveable hot press 12 along with the nano imprinting mold 11 with the nano scale pattern. Forming the nano scale pattern can further include heating the elastomer sheet 10 to a softening point or above. In some embodiments, heating the elastomer sheet 10 can be achieved using the hot press 12. In some embodiments, forming the nano scale pattern can include transferring the nano scale pattern by pressing the nano imprinting mold 11 on to the heated elastomer sheet 10. In some embodiments, forming the nano scale pattern can include collecting the elastomer sheet 10 at the second side 10b.

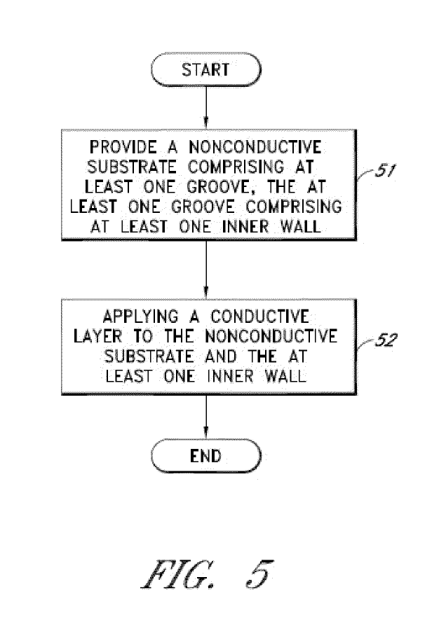

FIG. 4 depicts a schematic diagram of a system for preparing an electrode in accordance with some embodiments. The system in FIG. 4 illustrates a method for applying a conductive layer 25 to a nonconductive substrate 20 and at least one inner wall (not shown) in the substrate 20. In some embodiments, the conductive layer 25 can be at least partially transparent to light. In some embodiments, applying the conductive layer 25 includes low-temperature vapor deposition. In some embodiments, the low-temperature vapor deposition can be conducted at about 50° C. or lower, e.g., 50, 49, 48, 47, 45, 40, 35, 30, 25, 20, 15 degrees or lower, including ranges between any two of the preceding values and any range beneath any one of the preceding values.

As illustrated in FIG. 4, applying the conductive layer 25 can include setting an elastomer sheet 20 with a nano pattern formed on its surface at a third side 20a. In some embodiments, the elastomer sheet 20 with the nano pattern formed on its surface can be prepared by the system described in FIG. 3. In some embodiments, the elastomer sheet 20 can be fed continuously over a three dimensional stage 23 from the third side 20a to a fourth side 20b. Above the three dimensional stage 23 can be an electrode 22 along with a target 21. In some embodiments, the target 21 can be a B—Ga—ZnO sinter target for sputter deposition. In some embodiments, tension controllers 24 can be proximate the three dimensional stage 23 and above and below the elastomer sheet 20. The tension controllers 24 can apply tension to the elastomer sheet 10 to expand the elastomer sheet 20. Applying the conductive layer 25 can further include feeding the elastomer sheet 20 to the three dimensional stage 23. In some embodiments, applying the conductive layer 25 can include expanding the elastomer sheet 20. In some embodiments, applying the conductive layer 25 can include metalizing the elastomer sheet 20 to form at least one electrode. In some embodiments, metalizing the elastomer sheet 20 can include sputtering. In some embodiments, applying the conductive layer 25 can additionally include rolling up the elastomer sheet 20 to at the fourth side 20b.

In some embodiments, expanding the elastomer sheet 20 can be executed by at least one tension controller 24. The tension controller 24 can expand the elastomer sheet 20 so as to expand a width and/or length of a bottom surface of the grooves, as illustrated in FIG. 1B. In some embodiments, the tension controller 24 can apply tension on the elastomer sheet 20 while the conductive layer is applied, as illustrated in FIG. 1C. In some embodiments, metalizing can be performed using the B—Ga—ZnO sinter target. In some embodiments, the metalizing can be conducted at about 50° C. In some embodiments, as the elastomer sheet 20 is expanded, the conductive layer 25 can be patterned using a metal mask 26 that can be positioned above the elastomer sheet 20. In some embodiments, the elastomer sheet 20 can be expanded using only the tension controllers 24. In some embodiments, the elastomer sheet can be expanded using both the tension controllers 24 and the stage 23. In some embodiments, the elastomer sheet can be expanded using only the stage 23.

FIG. 5 depicts a schematic flowchart illustrating a method for preparing an electrode in accordance with some embodiments. In some embodiments, the process 50 can involve providing a nonconductive substrate that can include at least one groove. In some embodiments, the at least one groove can include at least one inner wall (block 51). In some embodiments, the nonconductive substrate can have at least one groove, and the at least one groove can have at least one inner wall. In some embodiments, the process further involves applying a conductive layer to a stretched form of the nonconductive substrate (block 52). In some embodiments, the conductive layer can be applied to the nonconductive substrate and the at least one inner wall. In some embodiments, the process 50 for preparing an electrode can be achieved using the systems described in FIGS. 3 and 4. In some embodiments, the substrate can be flexible and/or stretchable or any of the materials provided herein.

One skilled in the art will appreciate that, for this and other processes and methods disclosed herein, the functions performed in the processes and methods may be implemented in differing order. Furthermore, the outlined steps and operations are only provided as examples, and some of the steps and operations may be optional, combined into fewer steps and operations, or expanded into additional steps and operations without detracting from the essence of the disclosed embodiments.

In some embodiments, the substrate need not be stretched when the conductive layer is applied. In some embodiments, when a flexible and/or elastic conductive layer is used, the substrate can be in its relaxed or resting state when the conductive layer is applied.

In some embodiments, a method of using an interactive device is provided. In some embodiments, this can include providing a device that includes a flexible electrode. In some embodiments, one can then flex the flexible electrode to a flexed state, thereby interacting with the device. In some embodiments, the flexible electrode can include a conductive substrate having a plurality of grooves, with the plurality of grooves having inner walls, and a conductive layer disposed on the substrate and the inner walls of at least one of the plurality of grooves. In some embodiments, the flexible electrode can be any one or more of those described herein. In some embodiments, the method of using the interactive device can further include allowing the flexible electrode to return to a non-flexed state. In some embodiments, the interactive device can be any of those described herein.

### Example 1

### Methods of Making a Grid and/or Nano Pattern

The present example outlines some embodiments for making a nanopattern. An elastomer sheet can be run through a device (as depicted in FIG. 3). As the elastomer is run from across the device, it crosses the stage for hot stamping, a mold, and a pressing machine. The pattern on the mold will be the desired nanopattern, and it can be transferred to elastomer by pressing the mold against the sheet. The sheet will have been heated to allow the transfer of the nanopattern into the elastomer.

### Example 2

### Method of Making a Flexible Electrode

The present example outlines some embodiments of making a flexible electrode. The nanopatterned elastomer sheet produced in Example 1 is obtained and used as a base substrate in a device as depicted in FIG. 4. The elastomer layer sheet is passed over a 3D shaped stage having tension rollers before and after the stage, which results in expanding the sheet into a desired extended conformation. The tension control rollers are used so that a desired elongation is achieved on the arc of the stage.

A B—Ga—ZnO sinter target can be used as the target for a sputter based vapor deposition, which when combined with a mask (positioned between the target and the elastomer), allows for the formation of a desired electrode on the elastomer. The formation can occur at a temperature of about 50 degrees Centigrade and will result in the formation of a stretchable electrode.

### Example 3

### Methods of Using a Flexible Electrode Device

This example outlines some embodiments of using a device that includes a flexible electrode system. A device having a touch-screen display system is provided. The device has a substrate for the display that is elastomer based and thereby flexible and stretchable. The user turns the device on and views an image on the elastomer display. The user will stretch the elastomer substrate and/or bend the elastomer substrate during use of the device. However, the device will maintain an adequate level of its electrical contacts despite the movement of the substrate.

The present disclosure is not to be limited in terms of the particular embodiments described in this application, which are intended as illustrations of various aspects. Many modifications and variations can be made without departing from its spirit and scope, as will be apparent to those skilled in the art. Functionally equivalent methods and apparatuses within the scope of the disclosure, in addition to those enumerated herein, will be apparent to those skilled in the art from the foregoing descriptions. Such modifications and variations are intended to fall within the scope of the appended claims. The present disclosure is to be limited only by the terms of the appended claims, along with the full scope of equivalents to which such claims are entitled. It is to be understood that this disclosure is not limited to particular methods, compounds, compositions or systems, which can, of course, vary. It is also to be understood that the terminology used herein is for the purpose of describing particular embodiments only, and is not intended to be limiting.

With respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity.

It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to embodiments containing only one such recitation, even when the same claim includes the introductory phrases “one or more” or “at least one” and indefinite articles such as “a” or “an” (e.g., “a” and/or “an” should be interpreted to mean “at least one” or “one or more”); the same holds true for the use of definite articles used to introduce claim recitations. In addition, even if a specific number of an introduced claim recitation is explicitly recited, those skilled in the art will recognize that such recitation should be interpreted to mean at least the recited number (e.g., the bare recitation of “two recitations,” without other modifiers, means at least two recitations, or two or more recitations). Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

1. An electrode comprising:
a nonconductive substrate comprising a plurality of grooves, the plurality of grooves having inner walls; and
a conductive layer disposed on the substrate and the inner walls of at least one of the plurality of grooves.

2. The electrode of claim 1, wherein the substrate comprises a flexible material.

3. The electrode of claim 1, wherein the electrode is expandable.

4. The electrode of claim 1, wherein the electrode is flexible.

5. (canceled)

6. The electrode of claim 1, where the electrode is visibly transparent.

7. The electrode of claim 1, wherein the substrate comprises an elastomer, a polymer, PET, a high transparency polyimide, or a combination thereof.

8. (canceled)

9. The electrode of claim 1, wherein the substrate comprises polyimide, polyester, aramid, epoxy, PET, silicone, rubber, protein, cellulosic materials, or a combination thereof.

10. The electrode of claim 1, wherein the substrate comprises a block copolymer of methyl methacrylate and butyl acrylate.

11. The electrode of claim 1, wherein the substrate comprises a material having a glass transition temperature lower than about −40° C.

12. (canceled)

13. (canceled)

14. The electrode of claim 1, wherein the conductive layer comprises ZnO, ITO, PEDOT, carbon nanotubes, graphene, metal, metal alloy, conductive polymer, or combinations thereof.

15. The electrode of claim 1, wherein the ratio of the depth of the grooves to the width of the grooves is at least about one.

16. (canceled)

17. (canceled)

18. The electrode of claim 15, wherein the grooves have a width of about 195 nm to about 375 nm.

19. (canceled)

20. The electrode of claim 19, wherein the grooves have a depth of about 275 nm or more.

21. The electrode of claim 1, wherein the grooves are disposed in a grid pattern.

22. (canceled)

23. (canceled)

24. (canceled)

25. (canceled)

26. (canceled)

27. The electrode of claim 1, wherein the substrate is flexible.

28. The electrode of claim 1, wherein the conductive layer is at least partially transparent.

29. A method of preparing an electrode, the method comprising:
providing a nonconductive substrate comprising at least one groove, the at least one groove comprising at least one inner wall; and
applying a conductive layer to the nonconductive substrate and the at least one inner wall.

30. The method of claim 29, further comprising applying a tension to the substrate after providing the nonconducting substrate and before applying the conductive layer.

31. The method of claim 30, wherein a tension is applied to the substrate while the conductive layer is applied.

32. The method of claim 29, wherein the conductive layer is at least partially transparent to light.

33. (canceled)

34. The method of claim 29, wherein the conductive layer comprises at least one of ZnO, ITO, PEDOT, carbon nanotube, graphene, metal, metal alloy, or conductive polymer.

35. (canceled)

36. The method of claim 30, wherein the tension is sufficient to cause at least one groove to expand so that a width of a bottom surface of the groove expands.

37. (canceled)

38. (canceled)

39. (canceled)

40. (canceled)

41. (canceled)

42. The method of claim 41, wherein forming the nano scale pattern comprises:
feeding an elastomer sheet from a first side where the elastomer sheet is stored in a rolled-up form;
heating the elastomer sheet to a softening point or above;
transferring the nano scale pattern by pressing the nano imprinting mold on to the heated elastomer sheet; and
collecting the elastomer sheet at a second side.

43. The method of claim 42, further comprising:
setting the elastomer sheet with the nano pattern formed on its surface at a third side;
feeding the elastomer sheet to a three dimensional shaped stage;
expanding the elastomer sheet;
metalizing on the elastomer sheet to form at least one electrode; and
rolling up the elastomer sheet at a fourth side.

44. The method of claim 43, wherein expanding is executed by at least one tension controller.

45. The method of claim 43, wherein metalizing is performed using a B—Ga—ZnO sinter target.

46. (canceled)

47. A method of using an interactive device, the method comprising:
providing a device comprising a flexible electrode, wherein the flexible electrode comprises:
a nonconductive substrate comprising a plurality of grooves, the plurality of grooves having inner walls; and
a conductive layer disposed on the substrate and the inner walls of at least one of the plurality of grooves; and
flexing the flexible electrode to a flexed state, thereby interacting with the device.

48. (canceled)

49. (canceled)

50. (canceled)
